(19) United States
(12) Patent Application Publication
(10) Pub. No.: US 2009/0065889 A1
(43) Pub. Date: Mar. 12, 2009

(54) Semiconductor integrated circuit device and method for designing the same

(76) Inventor: Yasuyo Sogawa, Osaka (JP)

Correspondence Address: MCDERMOTT WILL & EMERY LLP, 600 13TH STREET, NW, WASHINGTON, DC, 20005-3096, US

(21) Appl. No.: 11/907,323

(22) Filed: Oct. 11, 2007

(30) Foreign Application Priority Data
Jan. 15, 2007 (JP) 2007-005794

(51) Int. Cl. G06F 17/50; H01L 27/00

(52) U.S. Cl. 257/499; 716/12; 257/E27.001

(57) ABSTRACT

A semiconductor integrated circuit device has a basic cell structure which allows avoidance of wiring congestion of signal lines or the like. The semiconductor integrated circuit device comprises a plurality of basic cells having predetermined functions, respectively, which are configured by connecting semiconductor elements via wirings. Each of the basic cells has a polygonal shape when viewed from the top. Moreover, a power source line is provided in an inner portion of the basic cell.

### CROSS-REFERENCE TO RELATED APPLICATION

This application claims priority under 35 U.S.C. § 119(a) on Japanese Patent Application No. 2007-005794 filed on Jan. 15, 2007, the entire contents of which are hereby incorporated by reference.

### BACKGROUND OF THE INVENTION

1. Field of the Invention

The present invention relates to a semiconductor integrated circuit device, and more particularly relates to a technique which is applied to ASIC (Application Specific Integrated Circuit) design and is used for optimizing a semiconductor integrated circuit.

2. Description of the Related Art

For ASIC designing, a design method such as a gate array method, a standard cell method, a custom method and the like is used (see, for example, Japanese Laid-Open Publication No. 8-23029). For example, according to a standard cell method, basic cell groups which have been optimally designed and have a plurality of functions are connected by wirings such as a power source line, a signal line and the like.

According to a standard cell method, basic cells shown in FIG. 9 each having a rectangular planar shape and power source lines 61 and 62 provided along upper and lower sides are disposed in a matrix as shown in FIG. 10. Then, a power source circuit as a source of electric power is connected to a power source line of each of the basic cells. Accordingly, electric power is supplied to each of the basic cells. Power supply from the power source circuit to the power source line of each of the basic cells is realized by forming a configuration called strap power source in which a trunk power source line extends in a single direction, a configuration called mesh power source in which power source lines are provided in a grid pattern (see, for example, Japanese Laid-Open Publication No. 2000-82743) and the like.

However, in the known technique, power source lines are provided along upper and lower sides of the basic cell. Thus, as shown in FIG. 10, in many cases, when basic cells are connected to one another via wirings such as signal lines 63 and 64 and the like, each of the signal lines 63 and 64 has to pass across the power source line 65. In such a case, the signal lines 63 and 64 have to be provided by using a different wiring layer from a wiring layer in which the power source line 65 is provided. Accordingly, wiring congestion easily occurs.

Moreover, in the known technique, in a wiring routing step after disposing the basic cells, the step of moving basic cells has been used as means for eliminating wiring congestion and achieving timing convergence. However, in such a case, all wirings for the moved basic cells have to be once cut off and then be connected again. Accordingly, work time of design is increased.

### SUMMARY OF THE INVENTION

In view of the above-described problems, the present invention has been devised. It is therefore an object of the present invention to provide a semiconductor integrated circuit device having a basic cell structure which allows avoidance of wiring congestion of a signal line and the like and suppression of increase in work time due to cut off and connection of wirings caused by movement of basic cells.

A present invention provides a semiconductor integrated circuit device in which semiconductor elements are provided on a surface of a semiconductor substrate and a wiring layer having a stacked structure for disposing wirings such as a power source line and a signal line is provided above the semiconductor elements, the device including a plurality of basic cells having predetermined functions, respectively, the plurality of basic cells being configured by connecting the semiconductor elements via the wirings, and each of the basic cells has a polygonal shape when viewed from the top or a polyhedral shape and has a power source structure in which the power source line is provided in an inner portion of the basic cell.

According to the present invention, in each of the basic cells, the power source line is provided in the inner portion of the basic cell. Thus, the signal line for connecting the basic cells can be easily disposed without passing across the power source line in the basic cells. Accordingly, the signal line can be provided in the same wiring layer in which the power source line is provided, so that the occurrence of wiring congestion can be suppressed.

A present invention provides a method for designing a semiconductor integrated circuit device, the method including the steps of: disposing basic cells; and routing wirings for the disposed basic cells, and each of the basic cells has a polygonal shape when viewed from the top or a polyhedral shape and has a power source structure in which the power source line is provided in an inner portion of the basic cell.

A present invention provides a semiconductor integrated circuit device in which semiconductor elements are provided on a surface of a semiconductor substrate and a wiring layer having a stacked structure for disposing wirings such as a power source line and a signal line is provided above the semiconductor elements, the device including a plurality of basic cells having predetermined functions, respectively, the plurality of basic cells being configured by connecting the semiconductor elements via the wirings, and each of the basic cells has a polygonal shape when viewed from the top or a polyhedral shape and has a power source structure in which one of power source lines is provided in an inner portion of the basic cell and the other one of the power source lines is provided in a peripheral portion of the basic cell.

A present invention provides a method for designing a semiconductor integrated circuit device, the method including the steps of: disposing basic cells; and routing wirings for the disposed basic cells, and each of the basic cells has a polygonal shape when viewed from the top or a polyhedral shape and has a power source structure in which one of the power source lines is provided in an inner portion of the basic cell and the other one of the power source lines is provided in a peripheral portion of the basic cell.

According to the present invention, the occurrence of wiring congestion of a signal line and the like can be suppressed.

### BRIEF DESCRIPTION OF THE DRAWINGS

FIG. 1 is a view illustrating a configuration of basic cells in a semiconductor integrated circuit device according to a first embodiment of the present invention.

FIG. 2 is a view illustrating an internal structure of a basic cell according to the first embodiment.

FIG. 3 is a view illustrating another internal structure of a basic cell according to the first embodiment.

FIG. 4 is a view illustrating a configuration of basic cells according to the first embodiment.

FIG. 5 is a view illustrating another configuration of basic cells according to the first embodiment.

FIG. 6 is a view illustrating another configuration of basic cells according to the first embodiment.

FIG. 7 is a view illustrating another configuration of basic cells according to the first embodiment.

FIG. 8 is a view illustrating an internal structure of a basic cell according to a second embodiment of the present invention.

FIG. 9 is a view illustrating an internal structure of a basic cell according to a known technique.

FIG. 10 is a view illustrating a configuration of a known semiconductor integrated circuit device.

### DESCRIPTION OF THE PREFERRED EMBODIMENTS

Hereafter, embodiments of the present invention will be described with reference to the accompanying drawings. Assuming a semiconductor integrated circuit device in which semiconductor elements are provided on a surface of a semiconductor substrate and a wiring layer having a stacked structure for providing wirings such as a power source line, a signal line and the like is provided above the semiconductor elements, the following embodiments will be described. Also, it is assumed that in the semiconductor integrated circuit device, a plurality of basic cells having predetermined functions, which are configured by connecting the semiconductor elements via wirings, are provided.

### First Embodiment

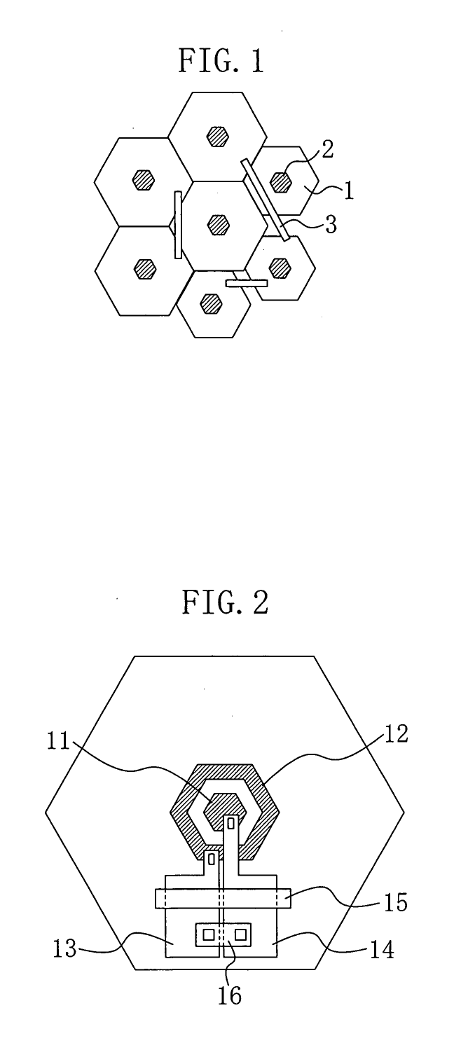

FIG. 1 is a view illustrating a configuration of basic cells in a semiconductor integrated circuit device according to a first embodiment of the present invention. In FIG. 1, 1 denotes a basic cell, 2 denotes a power source line provided in the basic cell, and 3 denotes a signal line. As shown in FIG. 1, each of basic cells 1 has a polygonal shape when viewed from the top. Each of the basic cells 1 has a power source structure in which a power source line 2 is provided in an inner portion of the basic cell 1. The power source line 2 in the basic cell 1 is connected to a power source circuit via a power source line such as a strap power source line, a mesh power source line and the like. In FIG. 1, each of the basic cells 1 has a hexagonal shape. However, the basic cell 1 may have some other polygonal shape than a hexagonal shape.

In each of the basic cells 1, the power source line 2 is provided in the inner portion thereof and thus a signal line 3 can be easily disposed without extending across the power source line 2. Accordingly, the signal line 3 can be provided in the same wiring layer in which the power source line 2 is disposed. Therefore, the occurrence of wiring congestion can be suppressed.

Also, in each of the basic cells 1, the power source line 2 is preferably disposed in a center portion, i.e., around the center of the basic cell. Thus, respective power source lines 2 of the basic cells 1 are disposed at substantially equal spaces, so that wiring congestion can be further avoided.

A basic cell may have a polygonal shape. A polygonal shape is effective when basic cells are disposed for a spherical LSI.

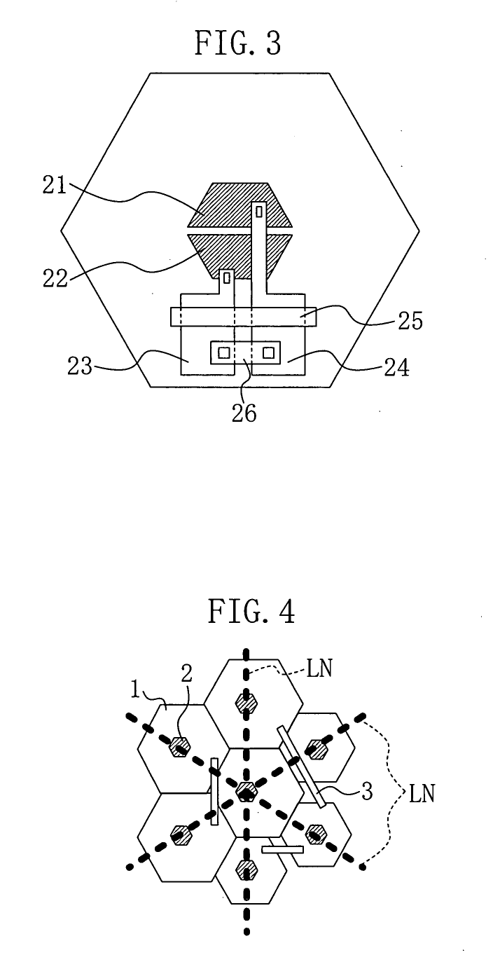

FIG. 2 and FIG. 3 are views illustrating internal structures of a basic cell according to this embodiment. Each of FIG. 2 and FIG. 3 illustrates an inverter circuit as an explanatory example. In FIG. 2, each of 11 and 12 denotes a power source line, each of 13 and 14 denotes a well region, 15 denotes a gate electrode and 16 denotes a data output section. Each of power source lines 11 and 12 has a ring shape and one of the power source lines 11 and 12 is provided for a supply potential and the other is provided for a substrate potential.

In FIG. 3, each of 21 and 22 denotes a power source line, each of 23 and 24 denotes a well region, 25 denotes a gate electrode and 26 denotes a data output section. Each of the power source lines 21 and 22 has a symmetric shape and one of the power source lines 21 and 22 is provided for a supply potential and the other is provided for a substrate potential.

As for the shape and structure of a power source line of a basic cell, various shapes and structures, such as the ring shape shown in FIG. 2, the symmetric shape shown in FIG. 3, a stacked layer type and the like, can be adopted. However, according to the present invention, as long as a power source line is provided in the inner portion of a basic cell, the shape and structure are not specifically limited.

Moreover, the power source lines 2 of the basic cells 1 are preferably disposed so as to be arranged in a straight line. For example, as shown in FIG. 4, when the power source lines 2 are disposed so as to be arranged along straight lines LN extending longitudinally, transversely and obliquely, a signal line extending in parallel to an associated one of the straight lines LN can be disposed without passing across the power source lines 2. Therefore, wiring congestion can be avoided.

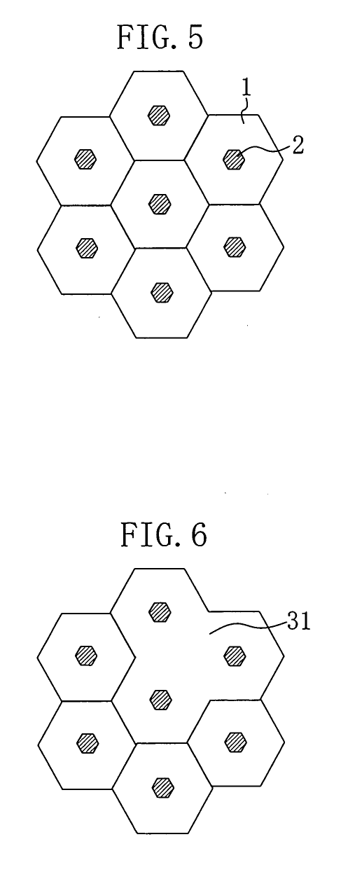

As shown in FIG. 5, the basic cells 1 may be formed so as to have the same shape and the same size. In such a case, the density of the disposed basic cells 1 is increased and a chip area can be reduced, thus resulting in reduction in costs.

A method for designing a semiconductor integrated circuit device according to this embodiment includes the step of disposing basic cells having the above-described structure and the step of routing wirings for disposed basic cells.

When a basic cell having the above-described structure is used, a power source line is disposed in the inner portion of the basic cell and therefore layout restrictions for a circumference of the basic cell can be reduced, compared to a known method. Thus, by rotating the basic cell, wiring congestion can be reduced and optimized timing can be achieved. Specifically, in the routing step, one or more of disposed basic cells may be rotated. In such a case, other wirings than wirings for the rotated basic cell do not have to be cut off and re-connected. Therefore, work time for design can be reduced.

In the disposing step, as shown in FIG. 6, a plurality of disposed basic cells may be combined together to form another basic cell 31.

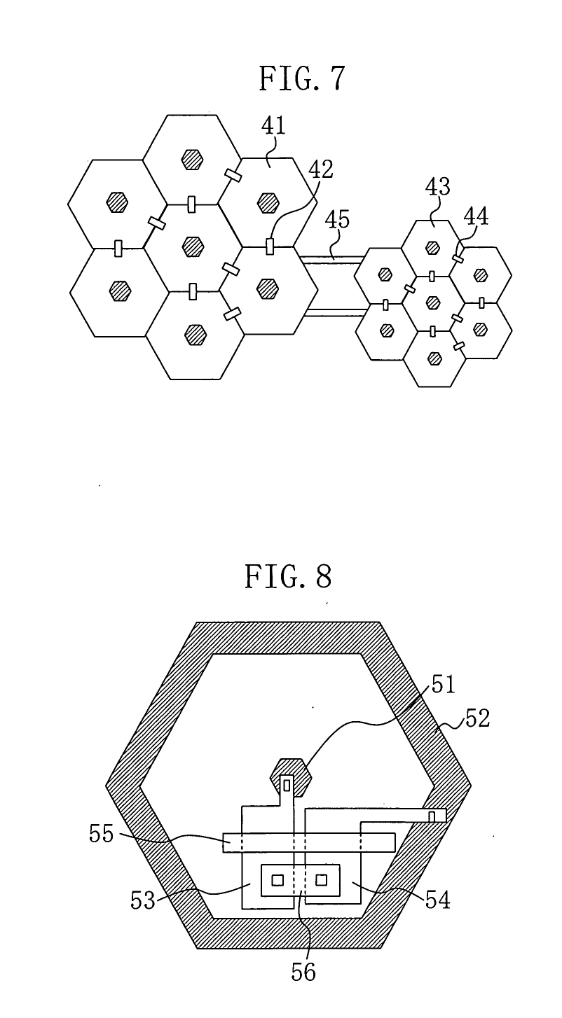

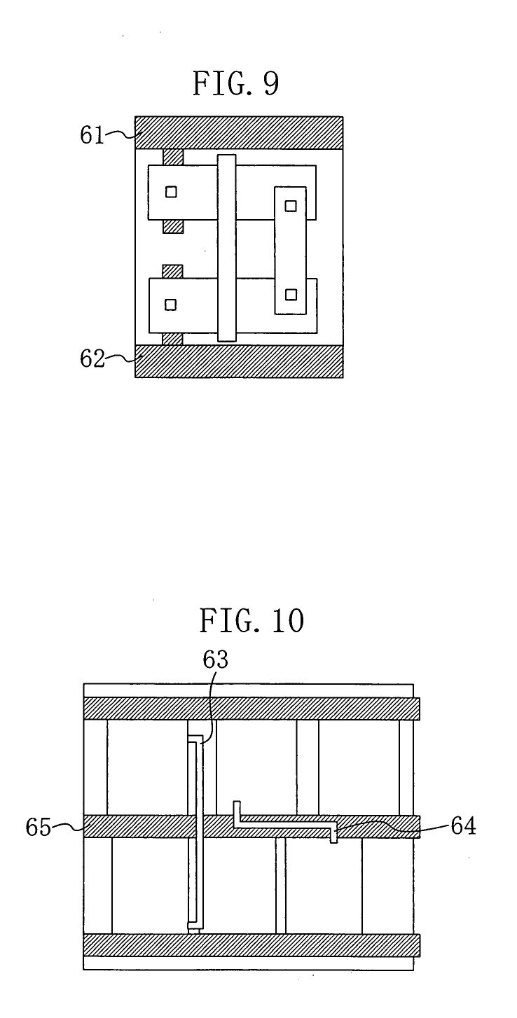

Moreover, in the routing step, when basic cells having the same shape and the same size are connected via wirings, the basic cells may be disposed so as to be located adjacent to one another and be connected via inner cell wirings. For example, as shown in FIG. 7, basic cells 41 having the same shape and the same size are disposed so as to be adjacent to one another and are connected via inner cell wirings 42. In the same manner, basic cells 43 having the same shape and the same size are disposed so as to be adjacent to one another and are connected via outer cell wirings 44. The basic cells 41 and the basic cells 43 are connected via the outer cell wirings 45.

### Second Embodiment

FIG. 8 is a view illustrating an internal structure of a basic cell in a semiconductor integrated circuit device according to a second embodiment of the present invention. FIG. 8 illustrates an inverter circuit as an explanatory example. In FIG. 8, each of 51 and 52 denotes a power source line, each of 53 and 54 denotes a well region, 55 denotes a gate electrode and 56 denotes a data output section. One of the power source lines 51 and 52 is provided for a supply potential and the other is provided for a substrate potential.

As shown in FIG. 8, a basic cell according to this embodiment has a polygonal shape when viewed from the top. The basic cell has a power source structure in which one of power source lines, i.e., the power source line 51 is provided in an inner portion of the basic cell and the other of power source lines, i.e., the power source line 52 is provided in a peripheral portion of the basic cell. In FIG. 8, the basic cell has a hexagonal shape but may have some other polygonal shape than a hexagonal shape. Moreover, respective shapes of the power source lines 51 and 52 are not limited to the shapes shown in FIG. 8. As long as one of the power source lines is provided in the inner portion of the basic cell and the other is provided in the peripheral portion of the basic cell, the shapes are not limited.

The shape of the basic cell may be a polyhedral shape.

Moreover, the power source line disposed in the inner portion of the basic cell is preferably provided in a center portion, i.e., around a center of the basic cell.

When a plurality of basic cells are provided in a semiconductor integrated circuit device, power source lines provided in the inner portion of the basic cells are preferably disposed so as to be arranged in a straight line. Each of the basic cells may have the same shape and the same size.

The method for designing a semiconductor integrated circuit device according to this embodiment includes the step of disposing a basic cell having the above-described structure and the step of routing wirings for disposed basic cells. In the routing step, one or more of disposed basic cells may be rotated. Moreover, in the disposing step, plural ones of the disposed basic cells may be combined together to form another basic cell.

When the above-described basic cell structure is adopted, a cell having a plurality of power source voltages can be formed in the case where the power source line 51 in the inner portion of the cell and the power source line 52 at the circumference of the cell are different in potential of power and power source. For example, a cell including a level shifter circuit provided therein and in which transistors operating at a power source voltage of 3.3 V and transistors operating at a power source voltage of 1.2 V are mounted together is an example of a cell having a plurality of power source voltages. Another example is a cell in which transistors which operate at the same power source voltage but operate at power source voltages supplied from a power source A and a power source B (or transistors operable at the same voltages which are supplied from different sources) are mounted together for the purpose of suppressing noise.

The present invention is useful for a semiconductor integrated circuit to which ASIC design is applied.

What is claimed is:

1. A semiconductor integrated circuit device in which semiconductor elements are provided on a surface of a semiconductor substrate and a wiring layer having a stacked structure for disposing wirings such as a power source line and a signal line is provided above the semiconductor elements, the device comprising:
a plurality of basic cells having predetermined functions, respectively, the plurality of basic cells being configured by connecting the semiconductor elements via the wirings,
wherein each of the basic cells has a polygonal shape when viewed from the top or a polyhedral shape and has a power source structure in which the power source line is provided in an inner portion of the basic cell.

2. The semiconductor integrated circuit device of claim 1, wherein in each of the basic cells, the power source line is disposed in a center portion of the basic cell.

3. The semiconductor integrated circuit device of claim 1, wherein the power source lines of the basic cells are disposed so as to be arranged in a straight line.

4. The semiconductor integrated circuit device of claim 1, wherein the basic cells have a same shape and a shape size.

5. A method for designing a semiconductor integrated circuit device, the method comprising the steps of:
disposing basic cells; and
routing wirings for the disposed basic cells,
wherein each of the basic cells has a polygonal shape when viewed from the top or a polyhedral shape and has a power source structure in which the power source line is provided in an inner portion of the basic cell.

6. The method of claim 5, wherein in the routing step, one or more of the disposed basic cells are rotated.

7. The method of claim 5, wherein in the disposing step, plural ones of the disposed basic cells are combined together to form another basic cell.

8. The method of claim 5, wherein in the routing step, when ones of the basic cells having a same shape and a same size are connected via wirings, said ones of the basic cells are disposed so as to be located adjacent to one another and are connected by inner cell wirings.

9. A semiconductor integrated circuit device in which semiconductor elements are provided on a surface of a semiconductor substrate and a wiring layer having a stacked structure for disposing wirings such as a power source line and a signal line is provided above the semiconductor elements, the device comprising:
a plurality of basic cells having predetermined functions, respectively, the plurality of basic cells being configured by connecting the semiconductor elements via the wirings,
wherein each of the basic cells has a polygonal shape when viewed from the top or a polyhedral shape and has a power source structure in which one of power source lines is provided in an inner portion of the basic cell and the other one of the power source lines is provided in a peripheral portion of the basic cell.

10. The semiconductor integrated circuit device of claim 9, wherein in each of the basic cells, said one of the power source line is disposed in a center portion of the basic cell.

11. The semiconductor integrated circuit device of claim 9, wherein said one of the power source lines of the basic cells are disposed so as to be arranged in a straight line.

12. The semiconductor integrated circuit device of claim 9, wherein the basic cells have a same shape and a same size.

13. A method for designing a semiconductor integrated circuit device, the method comprising the steps of:
disposing basic cells; and
routing wirings for the disposed basic cells,
wherein each of the basic cells has a polygonal shape when viewed from the top or a polyhedral shape and has a power source structure in which one of the power source lines is provided in an inner portion of the basic cell and the other one of the power source lines is provided in a peripheral portion of the basic cell.

14. The semiconductor integrated circuit device of claim 13, wherein in the routing step, one or more of the disposed basic cells are rotated.

15. The semiconductor integrated circuit device of claim 13, wherein in the disposing step, plural ones of the disposed basic cells are combined together to form another basic cell.
